(19) United States
(12) Patent Application Publication
(10) Pub. No.: US 2024/0183037 A1
(43) Pub. Date: Jun. 6, 2024

(54) APPARATUS AND METHOD FOR PROCESSING SUBSTRATE USING SUPERCRITICAL FLUID

(71) Applicant: SEMES CO., LTD., Cheonan-si (KR)

(72) Inventors: Hae Won CHOI, Daejeon (KR); Thomas Jongwan KWON, Gyeonggi-do (KR); Chengyeh HSU, Busan (KR)

(73) Assignee: SEMES CO., LTD., Cheonan-si (KR)

(21) Appl. No.: 18/494,979

(22) Filed: Oct. 26, 2023

(30) Foreign Application Priority Data
Dec. 6, 2022 (KR) 10-2022-0168334

(51) Int. Cl. C23C 18/16; C23C 18/18

(52) U.S. Cl. CPC C23C 18/1603; C23C 18/1658; C23C 18/1685; C23C 18/18

(57) ABSTRACT

A substrate processing method using a supercritical fluid is provided that can deposit a conformal film in a trench with a high aspect ratio and allows complete filling without voids. The substrate processing method comprises supplying a first process fluid containing a precursor and a first supercritical fluid to a reactor to raise a pressure of the reactor to a first pressure equal to or greater than a critical pressure, subsequently, first venting the reactor to lower the pressure in the reactor to a second pressure, subsequently, supplying a second process fluid containing a reducing fluid to the reactor to raise the pressure in the reactor to a third pressure, subsequently, second venting the reactor to lower the pressure in the reactor to a fourth pressure.

This application claims the benefit of Korean Patent Application No. 10-2022-0168334, filed on Dec. 6, 2022, in the Korean Intellectual Property Office, the disclosure of which is incorporated herein by reference in its entirety.

### BACKGROUND

### 1. Field

The present invention relates to a substrate processing apparatus and method using a supercritical fluid.

### 2. Description of the Related Art

As semiconductor devices become more highly integrated, individual circuit patterns are becoming more refined in order to implement more semiconductor devices in the same area. In other words, as the degree of integration of semiconductor devices increases, design rules for the components of semiconductor devices are decreasing.

In highly scaled semiconductor devices, the trench filling process is becoming increasingly difficult. When filling metal through ALD (Atomic Layer Deposition) or CVD (Chemical Vapor Deposition), trenches with high aspect ratios are not sufficiently filled and voids can occur inside the trench.

### SUMMARY

The problem to be solved by the present invention is to provide a substrate processing method using a supercritical fluid, which can deposit a conformal film in a trench with a high aspect ratio and allows void-free complete gap-filling.

Another problem to be solved by the present invention is to provide a substrate processing apparatus for performing the above method.

The objects of the present invention are not limited to the objects mentioned above, and other objects not mentioned will be clearly understood by those skilled in the art from the description below.

One aspect of the substrate processing method of the present invention to achieve the above problem comprises supplying a first process fluid containing a precursor and a first supercritical fluid to a reactor to raise a pressure of the reactor to a first pressure equal to or greater than a critical pressure, subsequently, first venting the reactor to lower the pressure in the reactor to a second pressure, subsequently, supplying a second process fluid containing a reducing fluid to the reactor to raise the pressure in the reactor to a third pressure, subsequently, second venting the reactor to lower the pressure in the reactor to a fourth pressure.

One aspect of the apparatus for processing a substrate comprises a reactor, a first process fluid supply unit, a second process fluid supply unit, and a vent unit, wherein the first process fluid supply unit supplies a first process fluid containing a precursor and a first supercritical fluid to the reactor to raise a pressure of the reactor to a first pressure equal to or greater than a critical pressure, subsequently, the vent unit first vents the reactor to lower the pressure in the reactor to a second pressure, subsequently, the second process fluid supply unit supplies a second process fluid containing a reducing fluid to raise the pressure in the reactor to a third pressure, subsequently, the vent unit second vents the reactor to lower the pressure in the reactor to a fourth pressure.

Specific details of other embodiments are included in the detailed description and drawings.

### BRIEF DESCRIPTION OF THE DRAWINGS

These and/or other aspects will become apparent and more readily appreciated from the following description of the embodiments, taken in conjunction with the accompanying drawings in which:

FIG. 1 is a diagram for explaining a substrate processing apparatus according to some embodiments of the present invention;

FIG. 2 is an implementation example of the substrate processing apparatus of FIG. 1;

FIG. 3 is a diagram illustrating a change in pressure of a reactor over time to explain a substrate processing method according to some embodiments of the present invention;

FIG. 4 is a timing diagram of the substrate processing apparatus of FIG. 1 for performing a substrate processing method according to some embodiments of the present invention;

FIG. 5 is a flow chart related to the operation of the substrate processing apparatus of FIG. 1 for performing a substrate processing method according to some embodiments of the present invention;

FIG. 6 is a diagram illustrating a process of filling a trench with metal using a substrate processing method according to some embodiments of the present invention;

FIG. 7 is a diagram for explaining a substrate processing method according to some embodiments of the present invention;

FIG. 8 is a diagram for explaining a substrate processing method according to some embodiments of the present invention;

FIGS. 9 and 10 are diagrams for explaining a substrate processing method according to some embodiments of the present invention;

FIG. 11 is a diagram for explaining a substrate processing apparatus according to some embodiments of the present invention;

FIG. 12 is a diagram illustrating pressure changes in a reactor over time to explain a substrate processing method according to some embodiments of the present invention;

FIG. 13 is a diagram illustrating a change in pressure of a reactor over time to explain a substrate processing method according to some embodiments of the present invention; and

FIG. 14 is a timing diagram of the substrate processing apparatus of FIG. 11 for performing a substrate processing method according to some embodiments of the present invention.

### DETAILED DESCRIPTION

Hereinafter, preferred embodiments of the present invention will be described in detail with reference to the attached drawings. The advantages and features of the present invention and methods for achieving them will become clear by referring to the embodiments described in detail below along with the accompanying drawings. However, the present invention is not limited to the embodiments disclosed below and may be implemented in various different forms. The present embodiments are merely intended to ensure that the disclosure of the present invention is complete and to full inform those skilled in the technical field to which the present invention pertains on the scope of the invention, and the present invention is only defined by the scope of the claims. Like reference numerals refer to like elements throughout the specification.

Spatially relative terms such as “below,” “beneath,” “lower,” “above,” “upper,” etc. can be used to easily describe the correlation between one elements or components and other elements or components. Spatially relative terms should be understood as terms that include different directions of the element during use or operation in addition to the direction shown in the drawings. For example, if an element shown in the drawings is turned over, an element described as “below” or “beneath” another element may be placed “above” the other element. Accordingly, the illustrative term “below” may include both downward and upward directions. Elements can also be oriented in other directions, so spatially relative terms can be interpreted according to orientation.

Although first, second, etc. are used to describe various components, elements and/or sections, it is understood that these components, elements and/or sections are not limited by these terms. These terms are merely used to distinguish one component, element, or section from other components, elements, or sections. Therefore, the first component, first element, or first section mentioned below may also be a second component, second element, or second section within the technical spirit of the present invention.

Hereinafter, embodiments of the present invention will be described in detail with reference to the accompanying drawings. In the description with reference to the accompanying drawings, identical or corresponding components will be assigned the same reference numbers regardless of the reference numerals, and the redundant explanation for this will be omitted.

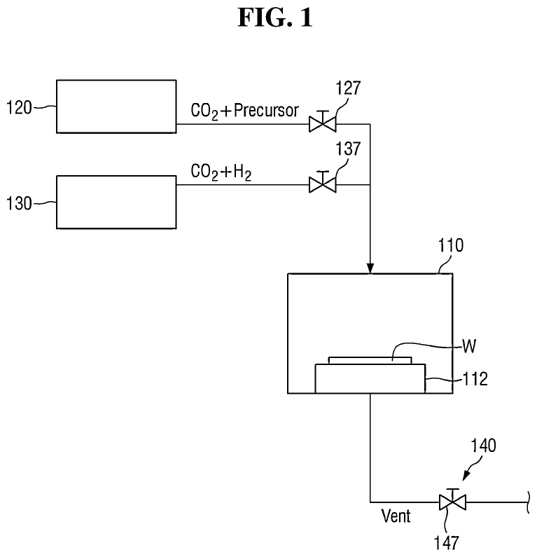

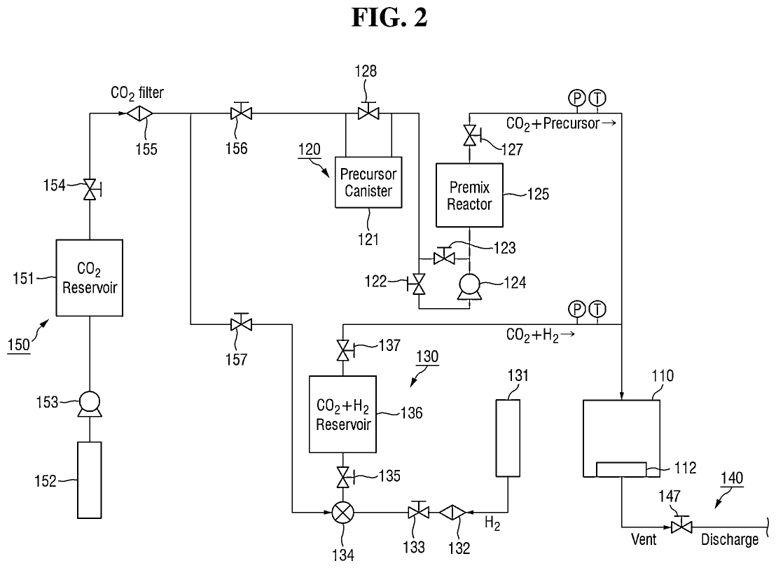

FIG. 1 is a diagram for explaining a substrate processing apparatus according to some embodiments of the present invention. FIG. 2 is an implementation example of the substrate processing apparatus of FIG. 1.

First, referring to FIG. 1, a substrate processing apparatus according to some embodiments of the present invention comprises a reactor 110, a first process fluid supply unit 120, a second process fluid supply unit 190 and a vent unit 140. A controller (not shown) may control the operations of the reactor 110, the first process fluid supply unit 120, the second process fluid supply unit 190 and the vent unit 140.

The reactor 110 is a space where a process for a supercritical fluid progresses. A support 112 for supporting the substrate W is located within the reactor 110.

A supercritical fluid is a substance placed at a temperature and pressure above a critical point, and has the diffusivity of a gas and the solubility of a liquid. Carbon dioxide (CO₂), water (H₂O), methane (CH₄), ethane (C₂H₆), propane (C₃H₈), ethylene (C₂H₄), propylene (C₃H₆), methanol (CH₃OH), ethanol (C₂H₅OH), and acetone (C₃H₆O), etc. may be used as supercritical fluids, but are not limited thereto. Below, carbon dioxide is explained as an example of a supercritical fluid.

The first process fluid supply unit 120 supplies a first process fluid containing a precursor and a first supercritical fluid into the reactor 110. That is, the first process fluid may include a precursor dissolved by the first supercritical fluid. The precursor may be a metal precursor, but is not limited thereto. The metal precursor is in the form of ML (where M is a metal, L is a ligand), and the metal (M) may comprise Ru, Mo, Cu, TiN, TaN, Al, Ti, Ta, Ni, Nb, Rh, Pd, Ir, Ag, Au, Zn, V, etc., but is not limited thereto. The ligand (L) may consist of only C and/or H, but is not limited thereto. That is, the ligand (L) may consist of only one of Cₓ, H_{y}, and CₓH_{y} (where x and y are natural numbers). Depending on whether the valve 127 is turned on or off, the first process fluid can be supplied to the reactor 110 or stopped.

The first process fluid may or may not be maintained in a supercritical state during the process of being supplied to the reactor 110 (that is, in the supply pipe connected to the reactor 110).

The first process fluid supply unit 120 may supply the first process fluid into the reactor 110 so that the internal pressure of the reactor 110 raises greater than or equal to the critical pressure. That is, the first process fluid may be in a supercritical state inside the reactor 110.

The second process fluid supply unit 190 supplies a second process fluid containing a reducing fluid into the reactor 110. Examples of reducing fluids may comprise oxygen (O₂), hydrogen (H₂), and ammonia (NH₃), but are not limited thereto. Optionally, the second process fluid may include a reducing fluid and a second supercritical fluid. That is, the second process fluid may include a reducing fluid dissolved by the second supercritical fluid. Depending on whether the valve 197 is turned on or off, the second process fluid can be supplied to the reactor 110 or stopped.

The second process fluid may or may not be maintained in a supercritical state during the process of being supplied to the reactor 110 (that is, in the supply pipe connected to the reactor 110).

The second process fluid supply unit 130 may supply the second process fluid into the reactor 110 so that the internal pressure of the reactor 110 raises equal to or greater than the critical pressure. That is, the second process fluid may be in a supercritical state inside the reactor 110.

The vent unit 140 vents the fluid inside the reactor 110 to the outside. When the third valve 147 is in the on state, the vent operation proceeds, and when the third valve 147 is in the off state, the vent operation is stopped.

Referring to FIG. 2, the first process fluid supply unit 120 and the second process fluid supply unit 130 receive a supercritical fluid (e.g., CO₂) from the supercritical fluid supply unit 150.

The supercritical fluid supply unit 150 comprises a first cylinder 152, a syringe pump 153, a first reservoir 151, a filter 155, and valves 154, 156, 157.

The first cylinder 152 stores liquefied carbon dioxide (LCO₂). For example, the first cylinder 152 may be controlled to about 40 bar and about 10° C., but is not limited thereto. Liquefied carbon dioxide is delivered to the first reservoir 151 through the syringe pump 153. The first reservoir 151 stores carbon dioxide. Within the first reservoir 151, carbon dioxide may be in a supercritical state. For example, the first reservoir 151 may be controlled to about 180 bar and about 60ºC, but is not limited to this. That is, the first reservoir 151 can be controlled greater than or equal to the critical pressure (7.38 Mpa=73.8 bar) and critical temperature (304.1K=30.95° C.) of carbon dioxide.

Through the filter 155 and the valve 156, carbon dioxide in a supercritical state is supplied to the first process fluid supply unit 120. The first process fluid supply unit 120 includes a precursor canister 121, valves 122, 123, 124, 127, and 128, and a premix reactor 125.

Carbon dioxide provided from the supercritical fluid supply unit 150 is supplied to the precursor canister 121. The precursor is extracted by carbon dioxide within the precursor canister 121 and provided to the premix reactor 125. The extracted precursor, along with carbon dioxide, may be delivered to the premix reactor 125 only through the valve 123, or may be delivered to the premix reactor 125 through the valve 122 and the syringe valve 124.

Additionally, carbon dioxide provided from the supercritical fluid supply unit 150 may be directly supplied to the premix reactor 125 through the valve 128, without passing through the precursor canister 121.

Within the premix reactor 125, a first process fluid (i.e., CO₂+Precursor) in which the precursor and carbon dioxide are mixed at a preset ratio is generated. By using carbon dioxide supplied without passing through the precursor canister 121, the preset ratio can be achieved. Additionally, the premix reactor 125 can be controlled to about 170 bar and about 60° ° C. to 120° C., but is not limited thereto.

Whether or not the first process fluid (i.e., CO₂+Precursor) generated in the premix reactor 125 is supplied to the reactor 110 is determined depending on whether the valve 127 is turned on or off.

Meanwhile, carbon dioxide in a supercritical state is provided to the second process fluid supply unit 130 through the filter 155 and the valve 257. The second process fluid supply unit 130 comprises a second cylinder 131, a mixing unit 134, a second reservoir 136, a filter 132, and valves 133, 135, and 137.

The second cylinder 131 stores a reducing fluid, for example, hydrogen (H₂). Hydrogen is provided to the mixing unit 134 through the filter 132 and valve 133.

Carbon dioxide provided from the supercritical fluid supply unit 150 and hydrogen provided from the second cylinder 131 are mixed in the mixing unit 134, and a second process fluid (i.e., CO₂+H₂) is generated.

In the second reservoir 136, a second process fluid is stored. The second process fluid within the second reservoir 136 may be in a supercritical state. The second reservoir 136 can be controlled to about 180 bar and about 60° ° C., but is not limited to this.

Whether or not the second process fluid (CO₂+H₂) stored in the second reservoir 136 is supplied to the reactor 110 is determined depending on whether the valve 137 is turned on or off.

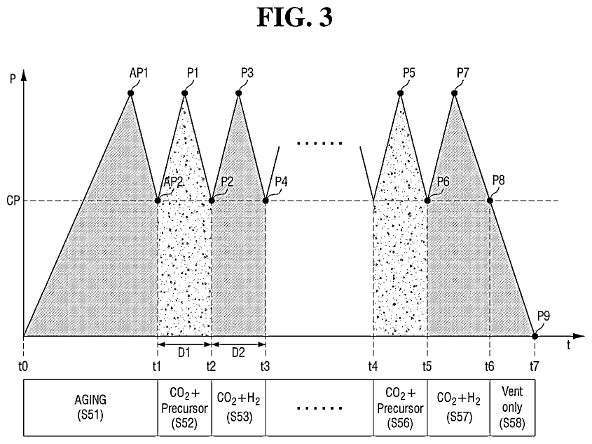

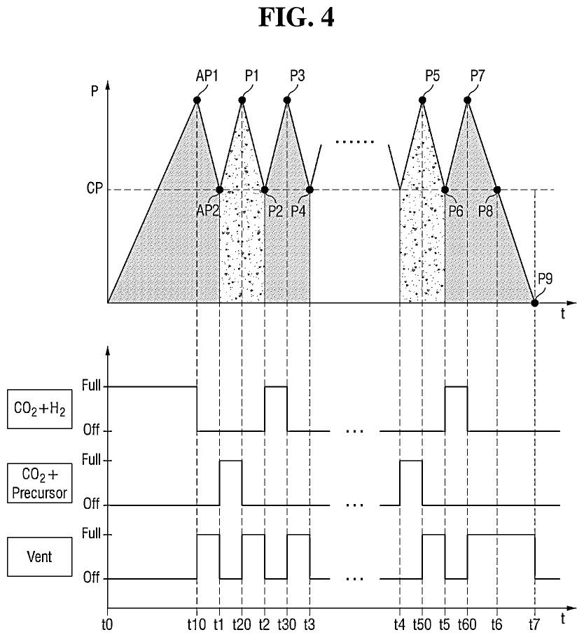

Below, a substrate processing method according to some embodiments of the present invention will be described using FIGS. 3 and 4. FIG. 3 is a diagram illustrating a change in pressure of a reactor over time to explain a substrate processing method according to some embodiments of the present invention. FIG. 4 is a timing diagram of the substrate processing apparatus of FIG. 1 for performing a substrate processing method according to some embodiments of the present invention.

Referring to FIG. 3, the substrate processing method according to some embodiments of the present invention includes an aging section (S51), a first process fluid supply section (S52, S56), a second process fluid supply section (S53, S57), and a vent section (S58).

In the aging section S51 (i.e., times t0 to t1), an aging operation to create an environment inside the reactor 110 is performed. Specifically, an aging fluid containing a supercritical fluid (e.g., CO₂) is supplied to raise the pressure of the reactor 110 to a pressure AP1 equal to or greater than the critical pressure CP. Optionally, the aging fluid may be the same as the second process fluid. That is, the aging fluid may contain carbon dioxide (CO₂) and hydrogen (H₂). Next, the aging fluid is vented from the reactor 110 to lower the pressure of the reactor 110 to pressure AP2. As shown, the pressure AP2 may also be equal to or greater than the critical pressure CP, but is not limited thereto.

Subsequently, in the first process fluid supply section S52 (i.e., times t1 to t2), the first process fluid including the precursor and the first supercritical fluid is supplied to the reactor 110. The pressure of the reactor 110 is raised to a pressure P1 equal to or greater than the critical pressure CP. Next, the first process fluid is vented from the reactor 110 to lower the pressure of the reactor 110 to pressure P2. As shown, the pressure P2 may also be equal to or greater than the critical pressure CP, but is not limited thereto. Pressure P1 may be 85 bar to 170 bar, and pressure P2 may be 75 bar to 160 bar, but is not limited thereto.

The precursor may be a metal precursor, but is not limited thereto. The metal precursor may be a combination of a metal (M) and a ligand (L). The metal (M) may include, but is not limited to, Ru, Mo, Cu, TiN, TaN, Al, Ti, Ta, Ni, Nb, Rh, Pd, Ir, Ag, Au, Zn, V, etc. The ligand (L) may consist of only C and/or H, but is not limited thereto. That is, the ligand (L) may consist of only one of Cₓ, H_{y}, and CₓH_{y} (where x and y are natural numbers).

Subsequently, in the second process fluid supply section S53 (i.e., times t2 to t3), the second process fluid containing the reducing fluid is supplied to the reactor 110. The second process fluid may include a reducing fluid and a second supercritical fluid. The pressure of the reactor 110 is raised to a pressure P3 equal to or greater than the critical pressure CP. Next, the second process fluid is vented from the reactor 110 to lower the pressure of the reactor 110 to pressure P4. As shown, the pressure P4 may also be equal to or greater than the critical pressure CP, but is not limited thereto. The pressure P3 may be 85 bar to 170 bar, and pressure P4 may be 75 bar to 160 bar, but is not limited thereto.

The duration D1 of the first process fluid supply section (e.g., S52) may be greater than or equal to the duration D2 of the second process fluid supply section (e.g., S53).

Subsequently, in the first process fluid supply section S56 (i.e., times t4 to t5), the first process fluid including the precursor and the first supercritical fluid is supplied to the reactor 110. The pressure of the reactor 110 is raised to a pressure P5 equal to or greater than the critical pressure CP and then lowered to a pressure P6. The pressure P6 may also be greater than or equal to the critical pressure CP, but is not limited thereto.

Subsequently, in the second process fluid supply section S57 (i.e., times t5 to t6), the second process fluid containing the reducing fluid is supplied to the reactor 110. The pressure of the reactor 110 is raised to a pressure P7 equal to or greater than the critical pressure CP and then lowered to a pressure P8. The pressure P8 may also be equal to or greater than the critical pressure CP, but is not limited thereto.

In this way, the first process fluid supply section (S52, S56) and the second process fluid supply section (S53, S57) can be repeated a preset number of times.

After repeating a preset number of times, the pressure of the reactor 110 may be lowered to a pressure P9 lower than the pressure P8 during the vent section (S58) (i.e., times t6 to t7). The pressure P9 may be a pressure lower than the critical pressure CP, for example, normal pressure or a pressure similar to normal pressure.

Meanwhile, the reason for providing the aging section (S51) before the first process fluid supply section (S52) is as follows. If the first process fluid is started to be supplied into the reactor 110 from the beginning without an aging section S51, the first process fluid may be concentrated near a portion of the substrate W (for example, the center region). Accordingly, by spreading the aging fluid inside the reactor 110 during the aging section S51, it is possible to prevent the first process fluid supplied thereafter from concentrating near a portion of the substrate W. In addition, the aging step serves to adjust the temperature and pressure inside the chamber to the actual process atmosphere conditions before starting to introduce the first process fluid.

In addition, as shown in FIG. 3, the supply of the first process fluid is adjusted in the first process fluid supply section (S52, S56) to raise and lower the pressure of the reactor 110, thereby creating a flow of the first process fluid within the reactor 110 (i.e., flow generation). Likewise, by controlling the supply of the second process fluid in the second process fluid supply section (S53, S57), a flow of the second process fluid can be created within the reactor 110 (i.e., flow generation). That is, flow momentum or turbulence is generated through the first process fluid supply sections (S52, S56) and the second process fluid supply sections (S53, S57) that proceed alternately. By doing this, the first process fluid and the second process fluid can easily penetrate into the space between the high aspect ratio trenches in the substrate W. Accordingly, even in complex structures, a conformal film can be stably created in a relatively short time and complete gap-filling can be achieved.

Additionally, in the vent section (S58), the pressure of the reactor 110 rapidly drops equal to or less than the critical pressure CP and near normal pressure. Accordingly, condensation occurs. That is, the metal precursor of the first process fluid condensates on the surface of the trench. Additionally, metal is precipitated by the reaction between the metal precursor and the reducing fluid. For example, if the metal precursor of the first process fluid is ML₂ (M is metal, L is ligand), and the reducing fluid of the second process fluid contains H₂, the ligand is removed by the reducing fluid as shown in the following chemical reaction equation, and metal is precipitated.

ML₂+H₂→M+2HL

Here, referring to FIGS. 1 and 4, at times t0 to t10, the second process fluid supply unit 130 supplies the second process fluid (CO₂+H₂) to the reactor 110 so that the pressure of the reactor 110 is equal to or greater than the critical pressure.

At times t10 to t1, the vent unit 140 vents the second process fluid inside the reactor 110 to lower the pressure of the reactor 110.

At times t1 to t20, the first process fluid supply unit 120 supplies the first process fluid (CO₂+Precursor) to the reactor 110 so that the pressure of the reactor 110 is equal to or greater than the critical pressure.

At times t20 to t2, the vent unit 140 vents the fluid inside the reactor 110 to lower the pressure of the reactor 110.

At times t2 to t30, the second process fluid supply unit 130 supplies the second process fluid (CO₂+H₂) to the reactor 110 so that the pressure of the reactor 110 is equal to or greater than the critical pressure.

At times t30 to t3, the vent unit 140 vents the fluid inside the reactor 110 to lower the pressure of the reactor 110.

At times t4 to t50, the first process fluid supply unit 120 supplies the first process fluid (CO₂+Precursor) to the reactor 110 so that the pressure of the reactor 110 is equal to or greater than the critical pressure.

At times t50 to t5, the vent unit 140 vents the fluid inside the reactor 110 to lower the pressure of the reactor 110.

At times t5 to t60, the second process fluid supply unit 130 supplies the second process fluid (CO₂+H₂) to the reactor 110 so that the pressure of the reactor 110 is equal to or greater than the critical pressure.

At times t60 to t6, the vent unit 140 vents the fluid inside the reactor 110 to lower the pressure of the reactor 110.

At times t6 to t7, the vent unit 140 continues to vent the fluid inside the reactor 110. As a result, the pressure of the reactor 110 may be lowered to normal pressure or a level similar thereto.

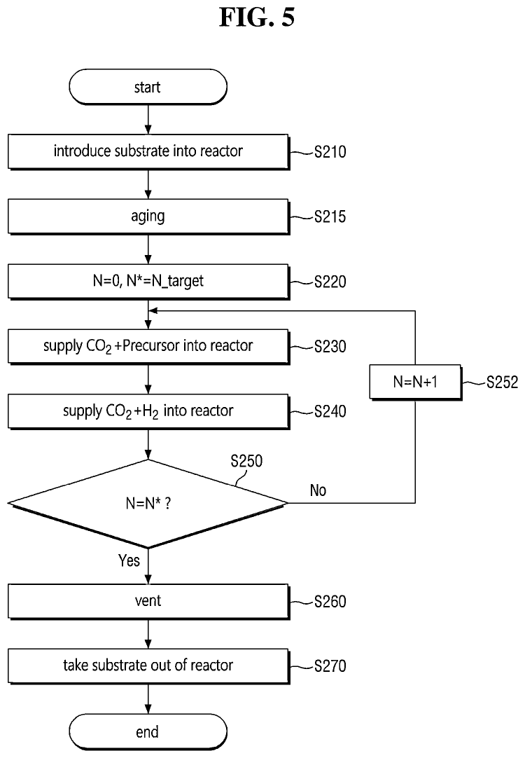

FIG. 5 is a flow chart related to the operation of the substrate processing apparatus of FIG. 1 for performing a substrate processing method according to some embodiments of the present invention. For convenience of explanation, content that is substantially the same as that described using FIG. 3 will be omitted.

Referring to FIG. 5, first, the substrate W is introduced into the reactor 110 (S210).

Next, an aging operation is performed (S215). As described above, an aging fluid (e.g., CO₂+H₂) containing a supercritical fluid (e.g., CO₂) is supplied to create a temperature and pressure environment inside the reactor 110.

Next, N (number of repetitions) is set to 0, and N* is set to the target value (N_target) (or the preset target repetition number) (S220).

Next, the first process fluid (CO₂+Precursor) is supplied into the reactor 110 (S230). By adjusting the supply amount of the first process fluid, a flow of the first process fluid is created within the reactor.

Next, the second process fluid (CO₂+H₂) is supplied into the reactor 110 (S240). By adjusting the supply amount of the second process fluid, a flow of the second process fluid is created within the reactor.

Next, it is checked whether N has reached the target value (N*) (S250).

Here, if N does not reach the target value (N*) (i.e., No in S250), the value of N is increased by 1 (N=N+1, S252). Again, the first process fluid supply (S230) and the second process fluid supply (S240) are repeated. In this way, the repetition number (N) of the first process fluid supply (S230) and the second process fluid supply (S240) is repeated a preset number (N*).

When N reaches the target value (N*) (i.e., Yes in S250), the fluid inside the reactor 110 is vented (S260).

Next, the substrate W is taken out of the reactor 110 (S270).

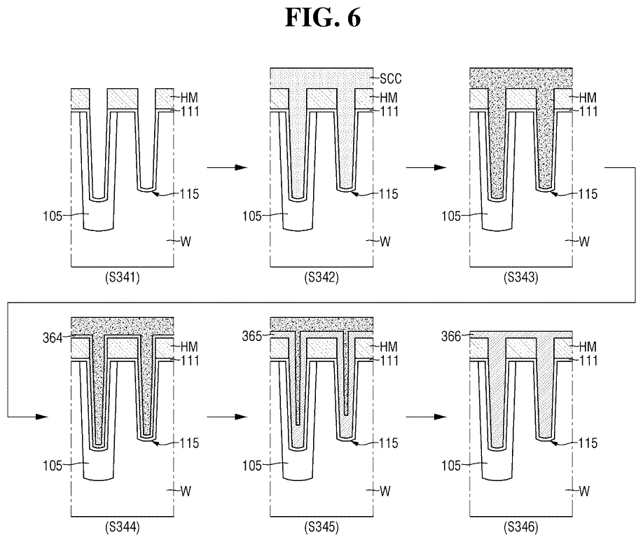

FIG. 6 is a diagram illustrating a process of filling a trench with metal using a substrate processing method according to some embodiments of the present invention. For example, FIG. 6 explains the process of forming a word line (metal layer) within a word line trench in DRAM.

Referring to FIG. 6, the substrate W on which the trench 115 is formed is placed inside the reactor 110 (S341). Specifically, a device isolation film 105 is formed on the substrate W, and a plurality of trenches 115 are formed. An insulating film 111 is formed conformally along the inner wall of the trench 115. Additionally, a hard mask (HM) is also formed.

Next, inside the reactor 110, a metal precursor (SCC) in a supercritical state penetrates between the trenches 115 (S342). Here, the penetrating metal precursor (SCC) in a supercritical state corresponds to the above-described first process fluid (i.e., CO₂+Precursor).

Metal precursors in a supercritical state have high penetrating power, very low surface tension, and high diffusivity compared to liquids. In addition, metal precursors in a supercritical state have high density and high solubility compared to gas. Due to these characteristics, using a metal precursor in a supercritical state allows for faster deposition compared to ALD (atomic layer deposition). Additionally, it has better step-coverage than CVD (Chemical Vapor Deposition) and can minimize defect/contamination risks.

As described above, the supply of the first process fluid is adjusted to raise and lower the pressure of the reactor 110, thereby creating a flow of the first process fluid within the reactor 110. Accordingly, the first process fluid more easily penetrates into the space between the trenches 115.

Next, a reducing fluid is provided inside the reactor 110 (S343). Here, the provided reducing fluid corresponds to the above-described second process fluid (CO₂+H₂).

As described above, the flow of the second process fluid can be created within the reactor 110 by adjusting the supply of the second process fluid to raise and then lower the pressure of the reactor 110. Accordingly, the second process fluid more easily penetrates into the space between the trenches 115.

Next, the metal precursor and the reducing fluid react to begin forming thin metal 364 inside the trench 115 (S344).

Subsequently, as described above, as the supply of the metal precursor and the supply of the reducing fluid are repeated a plurality of times, the thickness of the metal 365 begins to increase (S345).

Then, metal 366 completely fills trench 115. Metal 366 may also be formed on the upper surface of the trench 115 (S346). The metal 366 formed here is called a pre-metal layer.

Although not shown separately, in the drawing, atomic layer etching (ALE) is used to remove a portion of the free metal layer 366 to complete a metal layer (i.e., word line) that fills a portion of the trench 115. A capping film (a capping conductive film and/or a capping insulating film) may be additionally formed on the metal layer in the trench 115.

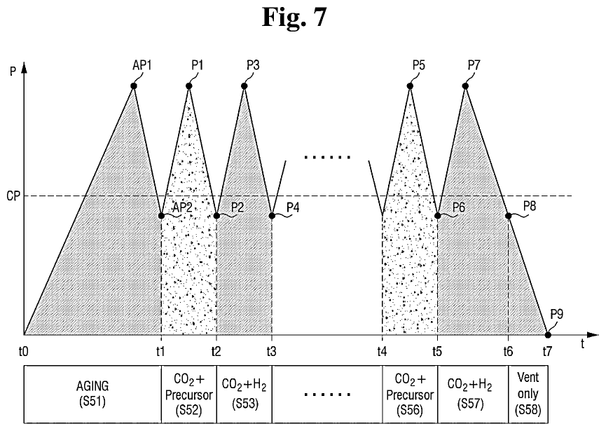

FIG. 7 is a diagram for explaining a substrate processing method according to some embodiments of the present invention. For convenience of explanation, differences from those described using FIG. 3 will be mainly explained.

In the embodiment described using FIG. 3, the lowest pressure AP2 in the aging section (S51), the lowest pressures P2, P6 in the first process fluid supply section (S52, S56), and the lowest pressures P4, P8 in the second process fluid supply section (S53, S57) are equal to or greater than the critical pressure CP.

On the other hand, referring to FIG. 7, the lowest pressure AP2 in the aging section (S51), the lowest pressures P2, P6 in the first process fluid supply section (S52, S56), and the lowest pressures P4, P8 in the second process fluid supply section (S53, S57) are less than the critical pressure CP.

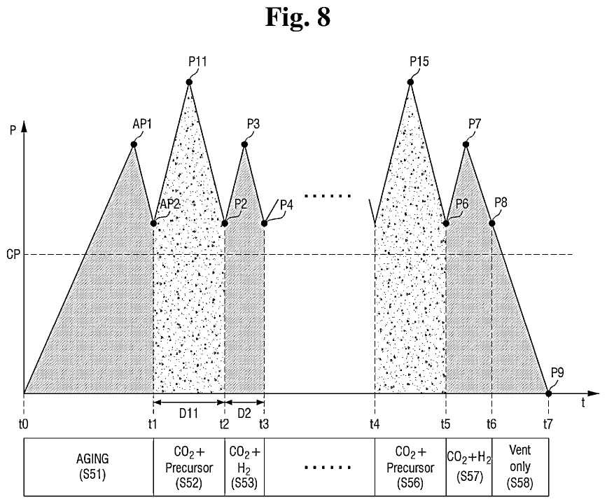

FIG. 8 is a diagram for explaining a substrate processing method according to some embodiments of the present invention. For convenience of explanation, differences from those described using FIG. 3 will be mainly explained.

In the embodiment described using FIG. 3, the highest pressure AP1 in the aging section (S51), the highest pressures P1, P5 in the first process fluid supply section (S52, S56), and the highest pressures P3, P7 in the second process fluid supply section (S53, S57) may be substantially the same.

On the other hand, referring to FIG. 8, the highest pressures P11, P15 in the first process fluid supply section (S52, S56) are greater than the highest pressures AP1, P3, P7 in the other sections (S51, S53, S57).

In order to do this, the supply time of the first process fluid should be further increased in the first process fluid supply section (S52, S56). Accordingly, in FIG. 8, the duration D11 of the first process fluid supply section S52 and S56 is sufficiently longer than the duration D2 of the second process fluid S53 and S57. In addition, the duration D11 of the first process fluid supply section S52 and S56 in FIG. 8 is sufficiently longer than the duration D1 of the first process fluid supply section S52 and S56 in FIG. 3.

By sufficiently extending the duration D11 of the first process fluid supply section (S52, S56) long enough, the precursor of the first process fluid can be stably supplied to the inside of the trench.

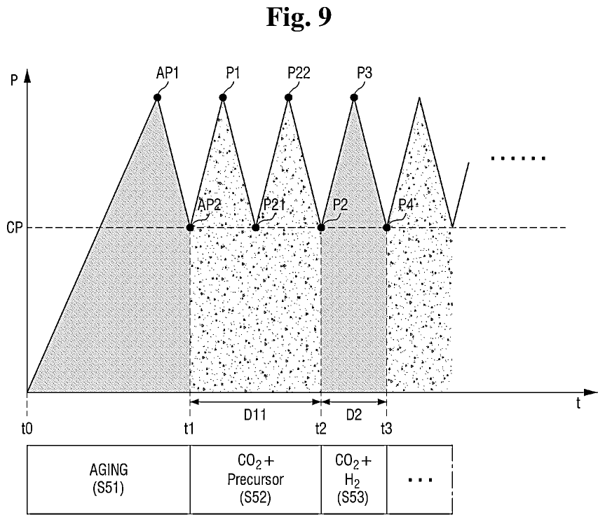

FIGS. 9 and 10 are diagrams for explaining a substrate processing method according to some embodiments of the present invention. For convenience of explanation, differences from those described using FIG. 3 will be mainly explained.

In the embodiment described using FIG. 3, one peak is formed in each of the first process fluid supply sections (S52 and S56). That is, the highest pressures P1, P5 are reached only once. One peak is also formed in each of the second process fluid supply sections (S53 and S57). That is, the highest pressures P3, P7 are reached only once.

Referring to FIG. 9, at least two peaks are formed in the first process fluid supply section (S52). That is, the highest pressures P1, P22 are reached at least twice. Accordingly, the lowest pressures P21, P2 may be reached at least twice in the first process fluid supply section (S52).

Accordingly, the duration D12 of the first process fluid supply section S52 is sufficiently longer than the duration D2 of the second process fluid S53 and S57.

Referring to FIG. 10, at least two peaks are formed in the first process fluid supply section (S52). In addition, at least two peaks are formed in each of the second process fluid supply sections (S53). That is, the highest pressures P3, P32 are reached at least twice. Accordingly, the lowest pressures P31, P4 may be reached at least twice in the second process fluid supply section (S53).

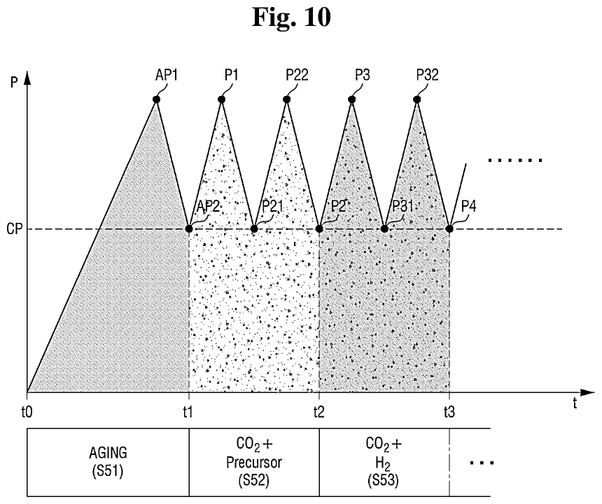

FIG. 11 is a diagram for explaining a substrate processing apparatus according to some embodiments of the present invention. For convenience of explanation, differences from those described using FIG. 2 will be mainly explained.

Referring to FIG. 11, the substrate processing apparatus according to some embodiments of the present invention further includes a rinse fluid supply unit 170. The rinse fluid supply unit 170 may include a valve 177 and may further include a reservoir capable of temporarily storing a supercritical fluid. A controller (not shown) may control the operations of the reactor 110, the first process fluid supply unit 120, the second process fluid supply unit 130, the vent unit 140, and the rinse fluid supply unit 170.

The rinse fluid supply unit 170 supplies rinse fluid to the reactor 110 to rinse the inside of the reactor 110. The rinse fluid supply unit 170 may receive a supercritical fluid (e.g., CO₂) from the supercritical fluid supply unit 150 and deliver it to the reactor 110. Whether or not the carbon dioxide in a supercritical state provided through the filter 155 is supplied to the reactor 110 is determined depending on whether the valve 177 is turned on or off.

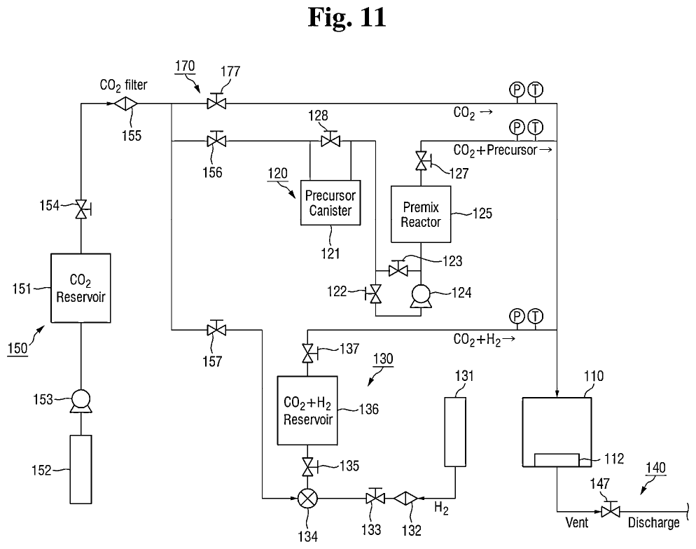

FIG. 12 is a diagram illustrating pressure changes in a reactor over time to explain a substrate processing method according to some embodiments of the present invention. For convenience of explanation, differences from those described using FIG. 3 will be mainly explained.

Referring to FIG. 12, the substrate processing method according to some embodiments of the present invention includes an aging section (S51), a first process fluid supply section (S52, S56), a second process fluid supply section (S53, S57), a vent section (S58) and a rinse section (S59).

After the vent section S58 ends, in the rinse section S59 (i.e., times t7 to t8), the rinse fluid providing unit (see 170 in FIG. 11) supplies a rinse fluid containing carbon dioxide to the reactor 110. Accordingly, the pressure of the reactor 110 is raised to a pressure RP1 equal to or greater than the critical pressure CP. Next, the rinse fluid is vented from the reactor 110 to remove residues inside the reactor 110.

By raising the pressure of the reactor 110 equal to or greater than the critical pressure CP and maintaining the rinse fluid in a supercritical state, residues (particularly, precursors that are not discharged) can be easily removed. The precursor is melted by supercritical fluid (CO₂) and easily discharged.

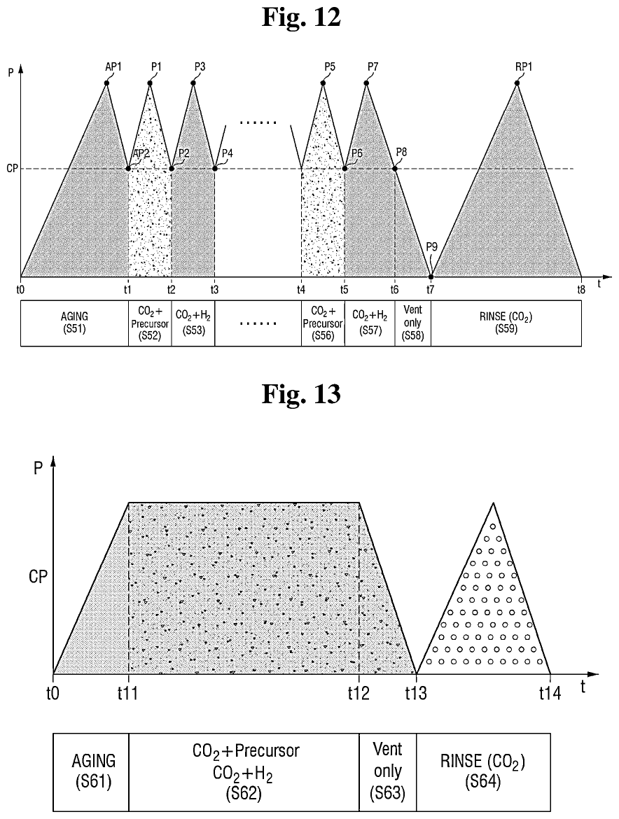

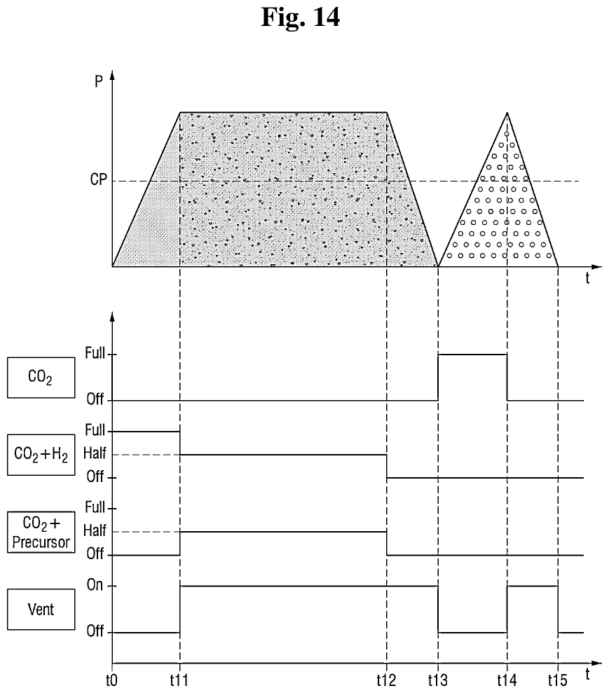

FIG. 13 is a diagram illustrating a change in pressure of a reactor over time to explain a substrate processing method according to some embodiments of the present invention. FIG. 14 is a timing diagram of the substrate processing apparatus of FIG. 11 for performing a substrate processing method according to some embodiments of the present invention. For convenience of explanation, the explanation will focus on differences from those described above.

Referring to FIG. 13, the substrate processing method according to some embodiments of the present invention includes an aging section (S61), a process fluid supply section (S62), a vent section (S63), and a rinse section (S64).

In the aging section S61 (i.e., times t0 to t11), an aging operation is performed to create an environment inside the reactor 110. Specifically, an aging fluid (e.g., CO₂+H₂) containing a supercritical fluid (e.g., CO₂) is supplied to raise the pressure of the reactor 110 equal to or greater than the critical pressure CP. Optionally, the aging fluid may be the same as the second process fluid. That is, the aging fluid may contain carbon dioxide (CO₂) and hydrogen (H₂).

Subsequently, in the process fluid supply section S62 (i.e., times t11 to t12), the first process fluid and the second process fluid are simultaneously supplied to the reactor 110. The first process fluid includes a precursor and a first supercritical fluid (e.g., CO₂), and the second process fluid includes a reducing fluid and a second supercritical fluid (e.g., CO₂). As shown, the pressure of reactor 110 can be maintained constant.

Subsequently, during the vent section S63 (i.e., times t12 to t13), the fluid inside the reactor 110 may be vented to lower the pressure of the reactor 110. For example, the pressure of the reactor 110 may be normal pressure or a pressure similar to normal pressure.

Subsequently, during the rinse section S64 (i.e., times t13 to t14), a rinse fluid containing carbon dioxide is supplied. Accordingly, the pressure of the reactor 110 is raised to a pressure equal to or greater than the critical pressure CP. Next, the rinse fluid is vented from the reactor 110 to remove residues inside the reactor 110.

Referring to FIGS. 11 and 14, at times t0 to t11, the second process fluid supply unit 130 supplies the second process fluid (CO₂+H₂) to the reactor 110 so that the pressure of the reactor 110 is equal to or greater than the critical pressure. Here, the valve 137 is fully opened to supply the second process fluid (CO₂+H₂).

At times t11 to t12, the first process fluid supply unit 120 supplies the first process fluid (CO₂+Precursor), and the second process fluid supply unit 130 supplies the second process fluid (CO₂+H₂). Here, the valve 127 is partially opened (half opened) to supply the first process fluid (CO₂+Precursor), and the valve 137 is partially opened (half opened) to supply the second process fluid (CO₂+H₂).

Meanwhile, the vent unit 140 also maintains in the on state. Since the vent unit 140 maintains in the on state, the pressure of the reactor 110 can be maintained constant even if the first process fluid (CO₂+Precursor) and the second process fluid (CO₂+H₂) are continuously supplied.

At times t12 to t13, the first process fluid supply unit 120 no longer supplies the first process fluid (CO₂+Precursor), and the second process fluid supply unit 130 no longer supplies the second process fluid (CO₂+H₂). The vent unit 140 continues to drain the fluid inside the reactor 110, thereby lowering the pressure of the reactor 110.

At times t13 to t14, the rinse fluid supply unit 170 supplies the rinse fluid (CO₂) to the reactor 110 to rinse the inside of the reactor 110. For example, the valve 177 is fully opened to supply the rinse fluid (CO₂), and when the pressure of the reactor 110 reaches a preset pressure (or a preset time has elapsed), the valve 177 is closed.

At times t14 to t15, the vent unit 140 drains the fluid inside the reactor 110, thereby lowering the pressure of the reactor 110.

Although embodiments of the present invention have been described with reference to the above and the attached drawings, those skilled in the art will understand that the present invention can be implemented in other specific forms without changing the technical idea or essential features. Therefore, the embodiments described above should be understood in all respects as illustrative and not restrictive.

What is claimed is:

1. A method for processing a substrate comprising:
supplying a first process fluid containing a precursor and a first supercritical fluid to a reactor to raise a pressure of the reactor to a first pressure equal to or greater than a critical pressure,
subsequently, first venting the reactor to lower the pressure in the reactor to a second pressure,
subsequently, supplying a second process fluid containing a reducing fluid to the reactor to raise the pressure in the reactor to a third pressure,
subsequently, second venting the reactor to lower the pressure in the reactor to a fourth pressure.

2. The method of claim 1, wherein the third pressure is greater than or equal to a critical pressure.

3. The method of claim 2, wherein the second pressure and the fourth pressure are greater than or equal to a critical pressure.

4. The method of claim 1, wherein supplying the first process fluid, first venting the reactor, supplying the second process fluid, and second venting the reactor are repeated a preset number of times.

5. The method of claim 4 further comprises,
lowering, after repeating the preset number of times, the pressure in the reactor to a fifth pressure less than the fourth pressure.

6. The method of claim 4 further comprises,
supplying, after repeating the preset number of times, a third supercritical fluid to the reactor to remove residue inside the reactor.

7. The method of claim 6 further comprises,
supplying a third process fluid containing a third supercritical fluid to the reactor to raise to a sixth pressure equal to or greater than a critical pressure,
subsequently, third venting the reactor to lower the pressure in the reactor to a seventh pressure.

8. The method of claim 4, wherein the precursor is MxLy, in which M is a metal, L is a ligand, and x and y are natural numbers, and the reducing fluid includes H₂,
wherein the precursor and the reducing fluid react to deposit a metal of a preset thickness on the substrate by repeating the preset number of times.

9. The method of claim 1, wherein the second process fluid includes the reducing fluid and a second supercritical fluid.

10. The method of claim 1, wherein a first period of supplying the first process fluid and performing the first venting is greater than or equal to a second period of supplying the second process fluid and performing the second venting.

11. The method of claim 1 further comprises,
performing an aging operation to create an environment inside the reactor before supplying the first process fluid,
wherein the aging operation comprises,
supplying an aging fluid containing a fourth supercritical fluid to the reactor to raise the pressure of the reactor to an eighth pressure equal to or greater than a critical pressure,
subsequently, fourth venting the reactor to lower the pressure in the reactor to a ninth pressure.

12. An apparatus for processing a substrate comprising:
a reactor, a first process fluid supply unit, a second process fluid supply unit, and a vent unit,
wherein the first process fluid supply unit supplies a first process fluid containing a precursor and a first supercritical fluid to the reactor to raise a pressure of the reactor to a first pressure equal to or greater than a critical pressure,
subsequently, the vent unit first vents the reactor to lower the pressure in the reactor to a second pressure,
subsequently, the second process fluid supply unit supplies a second process fluid containing a reducing fluid to raise the pressure in the reactor to a third pressure,
subsequently, the vent unit second vents the reactor to lower the pressure in the reactor to a fourth pressure.

13. The apparatus of claim 12, wherein the second to fourth pressures are equal to or greater than a critical pressure.

14. The apparatus of claim 12, wherein supplying the first process fluid, first venting the reactor, supplying the second process fluid, and second venting the reactor are repeated a preset number of times,
subsequently, the vent unit lowers the pressure in the reactor to a fifth pressure less than the fourth pressure.

15. The apparatus of claim 14 further comprises a rinse fluid providing unit,
wherein the rinse fluid providing unit, after repeating the preset number of times, supplies a rinse fluid containing a third supercritical fluid to the reactor to raise to a sixth pressure equal to or greater than a critical pressure to remove residue inside the reactor.

16. The apparatus of claim 14, wherein the precursor is MxLy, in which M is a metal, L is a ligand, and x and y are natural numbers, and the reducing fluid includes H₂,
wherein the precursor and the reducing fluid react to deposit metal of a preset thickness on the substrate by repeating the preset number of times.

17. A method for processing a substrate comprising:
supplying an aging fluid containing hydrogen and carbon dioxide to a reactor to raise a pressure of the reactor to a first aging pressure,
venting the reactor to lower the pressure in the reactor to a second aging pressure,
supplying a first process fluid containing a metal precursor and carbon dioxide to the reactor to raise the pressure of the reactor to a first pressure,
first venting the reactor to lower the pressure in the reactor to a second pressure,
supplying a second process fluid containing hydrogen and carbon dioxide to the reactor to raise the pressure in the reactor to a third pressure,
second venting the reactor to lower a pressure in the reactor to a fourth pressure,
wherein the first aging pressure, the first pressure, and the third pressure are greater than or equal to a critical pressure.

18. The method of claim 17, wherein the second aging pressure, the second pressure, and the fourth pressure are greater than or equal to a critical pressure.

19. The method of claim 17, wherein the first pressure is 85 to 170 bar, and the second pressure is 75 to 160 bar,
wherein the third pressure is 85 to 170 bar, and the fourth pressure is 75 to 160 bar.

20. The method of claim 17 further comprises,
repeating supplying the first process fluid, first venting the reactor, supplying the second process fluid, and second venting the reactor a preset number of times,
subsequently, additionally lowering the pressure of the reactor to a fifth pressure less than a critical pressure,
subsequently, supplying a rinse fluid containing carbon dioxide to the reactor to raise the pressure of the reactor to a first rinse pressure equal to or greater than a critical pressure to remove residue inside the reactor.
